(19) United States
(12) Patent Application Publication
(10) Pub. No.: US 2011/0143506 A1
(43) Pub. Date: Jun. 16, 2011

(54) METHOD FOR FABRICATING A SEMICONDUCTOR MEMORY DEVICE

(76) Inventor: Sang-Yun Lee, Beaverton, OR (US)

(21) Appl. No.: 12/635,496

(22) Filed: Dec. 10, 2009

(51) Int. Cl. H01L 21/8239

(52) U.S. Cl. 438/238; 257/E21.645

(57) ABSTRACT

A method for fabricating semiconductor memory device includes providing a first semiconductor substrate, and forming a first storage device on the first semiconductor substrate. The method includes forming a switching device on the first storage device, and forming a second storage devices on the switching device. Logic devices are formed below the first storage devices.

### BACKGROUND OF THE INVENTION

1. Field of the Invention

This invention relates to method for fabricating semiconductor memory device, more specifically relates to a method for fabricating three-dimensional semiconductor memory device to increase chip density.

2. Description of the Related Art

Along with the advance in semiconductor manufacturing technology, a requirement for smaller pattern size and shorter distance between patterns on the chip. Using the smaller pattern size induces problems like high leakage currents. This is one of the reasons which limits increasing chip density by decreasing pattern size.

In order to achieve high density semiconductor devices, recent developments focus on stacking semiconductor device on the substrate in three-dimensional structure.

### BRIEF SUMMARY OF THE INVENTION

The present invention employs a method of fabricating three-dimensional semiconductor memory device which has vertically structured electrical devices by substrates bonding.

The method of forming a three-dimensional structure semiconductor memory device is comprised of, forming first storage devices on the first semiconductor substrate; forming switching devices on the first storage devices; and forming second storage devices on the switching devices.

In another embodiment, the method of fabricating semiconductor memory device according to this invention is comprised of, forming switching devices on the first semiconductor substrate; forming first storage devices on the switching devices which is electrically connected to the switching devices; and forming second storage devices on the backside of the first semiconductor substrate which are electrically connected to the switching devices.

### BRIEF DESCRIPTION OF THE DRAWINGS

FIGS. 1 to 11 are sectional views of steps in a method of forming a semiconductor memory device, in accordance with a first embodiment this invention.

FIGS. 12 to 19 are sectional views of steps in a method of forming a semiconductor memory device, in accordance with a second embodiment of this invention.

FIGS. 20 to 27 are sectional views of steps in a method of forming a semiconductor memory device, in accordance with a third embodiment of this invention.

FIGS. 28 to 37 are sectional views of steps in a method of forming a semiconductor memory device, in accordance with a fourth embodiment of this invention.

### DETAILED DESCRIPTION OF THE INVENTION

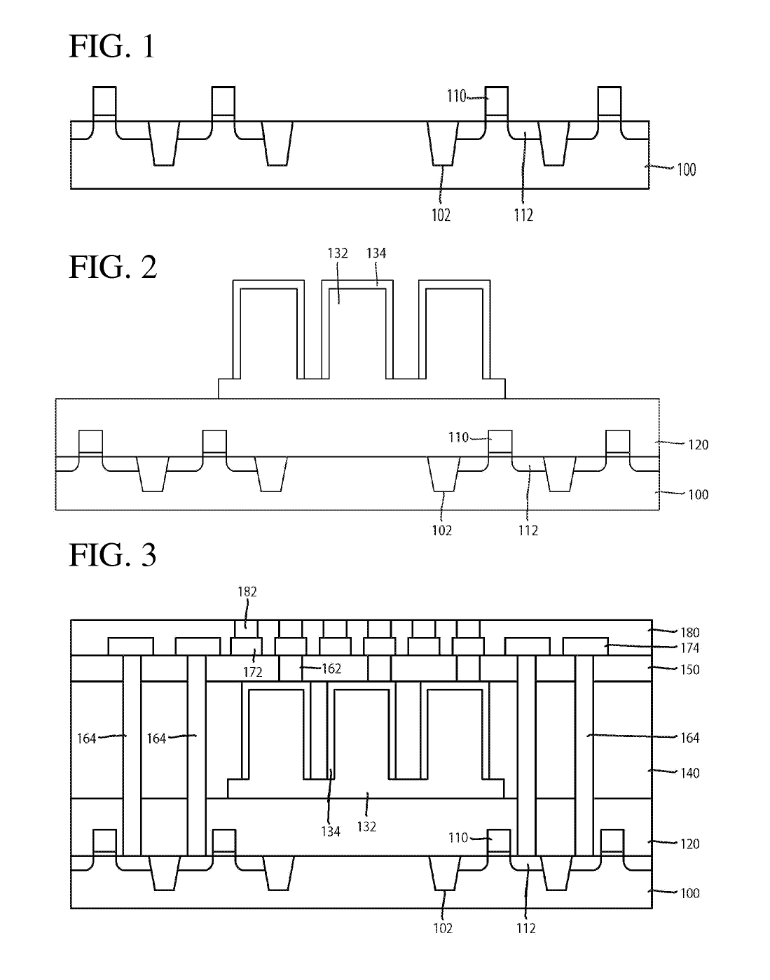

FIGS. 1 to 11 illustrate a first embodiment of the semiconductor memory device in accordance with this invention.

In FIG. 1, logic devices are formed on a first semiconductor substrate 100. The logic devices are comprised of NMOS and PMOS transistors 110, 112, resistors (not illustrated) and interconnections (not illustrated).

More specifically, isolations 102 are formed in the first semiconductor substrate 100 and define active region. The first semiconductor substrate 100 can be bulk silicon, bulk silicon-germanium, or a semiconductor substrate on which silicon or silicon-germanium epitaxial layer is formed. Also, the first semiconductor substrate 100 can be Silicon-on-sapphire (SOS), silicon-on-insulator (SOI), thin film transistor (TFT), doped and undoped semiconductors, silicon epitaxial layer formed on the base semiconductor, or other semiconductor structures well known to those who are skilled in the art.

The isolations 102 can be formed by forming trenches on the first semiconductor substrate 100, and then fill-in the trenches with dielectric materials such as High Density Plasma (HDP) oxide.

Before forming the isolations 102, well regions can be formed in the first semiconductor substrate at pre-defined regions to form NMOS or PMOS transistors. The well regions can be formed by ion implanting dopants into the surface of the first semiconductor substrate 100.

After defining the well regions in the first semiconductor substrate 100, gate electrodes 110 are formed on the first semiconductor substrate 100 by stacking and patterning gate dielectric film and gate conductor. After forming the gate conductors 110, source/drain regions 112 are formed by ion-implanting dopants into each side of the gate electrodes 110 in the first semiconductor substrate 100. This completes forming transistors on the first semiconductor substrate 100.

In FIG. 2, a first interlayer dielectric film 120 is formed by depositing dielectric film with good step coverage. Resistors (not illustrated), diodes (not illustrated) and interconnections (not illustrated) can be included in the first interlayer dielectric film 120.

As following steps, lower region storage devices are formed on the first interlayer dielectric film 120. In this embodiment of this invention, the lower region storage devices can be formed as capacitors. In another embodiment, the storage devices can be formed using phase change materials. In the other embodiment, the storage devices can be formed with high-k material using its remnant polarization characteristics.

When capacitors are used to form the storage devices, the capacitors can be shaped in various shapes such as stack type, pillar type, cylinder type. The stack type capacitors can have first electrodes and second electrodes to be stacked face to face. The pillar type capacitors can have pillar shaped first electrodes and the second electrodes are formed to surround the outer surface of the first electrodes conformal. And the cylinder type capacitors can have cylinder shaped first electrodes and the second electrodes are formed to cover the inner surface of the first electrodes conformal. In this embodiment of the invention, forming the cylinder type capacitors 132, 134 will be explained.

More specifically, the first electrodes 132, which are plate electrodes, are formed on the first interlayer dielectric film 120 in which the logic devices are included. That is, the pillar shaped first electrodes 132 are formed by depositing enough thickness of conducting film on the first interlayer dielectric film 120 and then performing photolithography and etch processes to the conducting film.

After forming the first electrodes 132, a dielectric film (not illustrated) and a conducting film for second electrodes are deposited conformal on the surface of the first electrodes 132. As next steps, the second conducting film for the second electrodes is etched to separate the second conducting film into the second electrodes 134. In other words, the second electrodes 134 can be formed covering the first electrodes 132 pillars and the second electrodes 134 are separated from each others. The second electrodes 134 are storage node electrodes, and can be formed as cylinder shaped which have open bottoms.

When forming the cylinder type lower region capacitors 132, 134, the first and second electrodes can be formed with poly silicon or metal films, and the dielectric film (not illustrated) can be formed with Tantalum Oxide (Ta₂O₅) or Aluminum Oxide (Al₂O₃), or stacked films such as Tantalum Oxide/Titanium Oxide or Aluminum Oxide/Titanium Oxide.

In FIG. 3, after forming capacitors 132, 134, an insulating film is deposited onto whole surface of the semiconductor substrate 100. As a following step, a planarization process such as CMP or etch back is performed to form a second interlayer dielectric film 140, 150.

As following steps, contact plugs 162 for lower region storage nodes which are individually connected to the second electrodes 134 and contact plugs 164 for logic which are individually connected to the transistors 110, 112. Conducting lines 174 are formed on the contact plugs 162, 164. At the same time, conducting lines which are not connected to the contact plugs can be also formed. These conducting lines which are not connected to the contact plugs are used as bit lines 172 which will be connected to the switching devices at the latter process steps. That is, on the top regions of the capacitors 132, 134, bit lines 172 and conducting lines 174 can be formed side by side.

A third interlayer dielectric film 180 is formed to cover the bit lines 172 and conducting lines 174, and then contact plugs 182 to which are electrically connected to the bit lines 172 and the second electrodes 134 respectively, are formed in the third interlayer dielectric film 180.

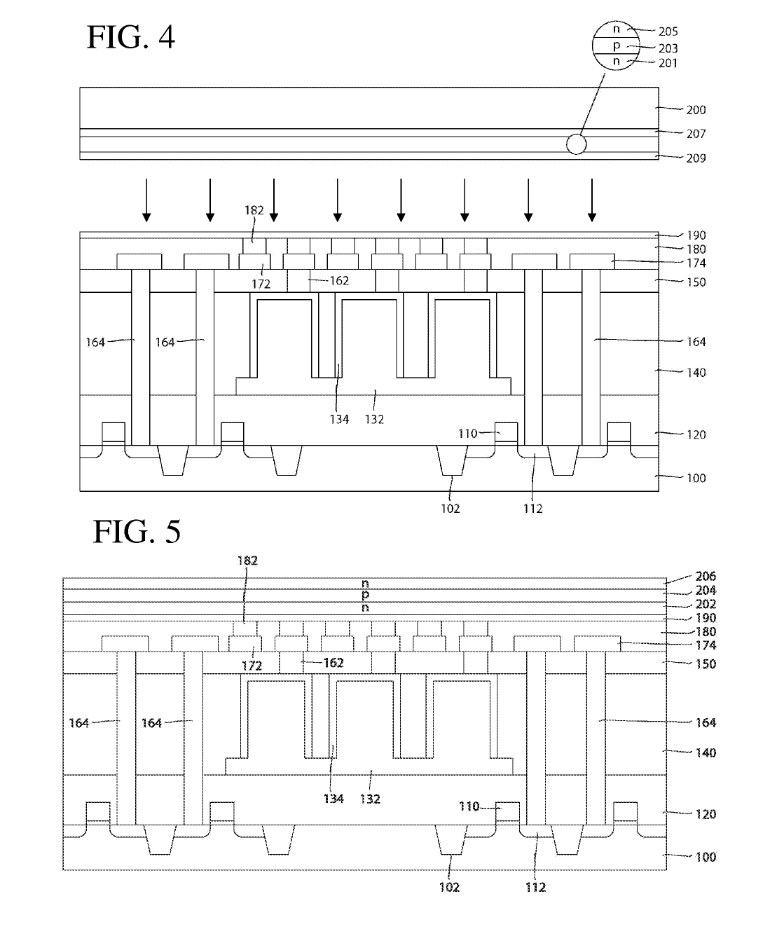

In FIG. 4, a bonding layer 190 is formed on top of the third interlayer dielectric film 180 which is at most upper layer of the first semiconductor substrate 100. The bonding layer will be used to bond a second semiconductor substrate 200 in where switching devices will be formed.

The bonding layer 190 can be formed with, for example, photo-setting adhesive such as reaction-setting adhesive, thermal-setting adhesive, photo-setting adhesive such as UV-setting adhesive, or anaerobe adhesive. Further, the bonding layer can be, such as, metallic bonds (Ti, TiN, Al), epoxy, acrylate, or silicon adhesives.

When the bonding layer 190 is formed with metallic materials, the metallic material can be formed with material that has lower melting point than those of conducting materials used for contact plugs 162, 164 and conducting lines 172, 174. And, the bonding layer 190 can be formed with materials that can be re-flowed at a lower temperature planarization process so that it can prevent formation of voids between the second semiconductor substrate 200 and the bonding layer 190. The bonding layer 190 can increase the bonding strength when bonding the second semiconductor 200 onto the bonding layer 190, and also decrease micro defects during the bonding process.

As a following step, the second semiconductor substrate 200 is bonded onto the bonding layer 190. Specifically, the second semiconductor substrate 200 can be a single crystalline semiconductor substrate which includes multiple doped layers 201, 203, 205 which are included in pre-defined depths from the surface of the second semiconductor substrate 200. The multiple doped layers 201, 203, 205 can be formed by ion-implanting dopants into the single crystalline semiconductor substrate, or adding dopants during an epitaxial process to form a single crystalline semiconductor substrate.

The multiple doped layers 200 can be formed to have n-type doped layers 201, 205 and p-type doped layers 203 are arranged alternatively. In this embodiment of this invention, NMOS transistors are formed as a upper region switching devices so that n-type doped layer 201, among the multiple doped layers 201, 203, 205, is interfaced to the bonding layer 190.

Also, the second semiconductor substrate 200 includes a detaching layer 207 at the interface of the multiple doped layers 201, 230, 205 and the second single crystalline semiconductor substrate. The detaching layer can be porous layer, oxide film, nitride film, organic bonding film, or strained layer such as Si—Ge interface.

Among the technologies to form the detaching layer, one of the well known technologies is Hydrogen Exfoliating Implant. This method has a critical disadvantage which can destroy lattice structures of the substrate because it uses high amount of ion implantation. In order to recover the destroyed lattice structures, the substrate should be cured by heat treatment in very high temperature long time. This kind of high temperature heat treatment can damage cell devices in the lower regions.

The detaching layer 207 can be used to prevent multiple doped layers 201, 203, 205 not to be removed when removing single crystalline semiconductor substrate after bonding. The detaching layer also helps to precisely and easily detach the single crystalline semiconductor substrate while remaining the multiple doped layers 201, 203, 205.

In FIG. 5, the second semiconductor substrate 200 is bonded to the surface of the multiple doped layers 201, 203, 205 to be face to face to the bonding layer 190. After bonding, the substrates can be treated in a pre-defined pressure and temperature to increase bonding strength.

When bonding the second semiconductor substrate 200 onto the bonding layer, no precise alignment is required because there are no patterns yet formed on the second semiconductor substrate 200.

After bonding the second semiconductor substrate 200 onto the bonding layer 190, all regions of the second semiconductor substrate 200 are removed while only remaining the multiple doped layers 200. As a result, only the multiple doped layers 201, 203, 205 are formed on the bonding layer 190.

More specifically, after bonding, the surface of the single crystalline semiconductor substrate 200 is grinded, polished, or etched until the detaching layer 207 is exposed. After the detaching layer 207 is exposed, anisotropic or isotropic etch process is performed to expose the multiple doped layers 201, 203, 205. That is, n-type doped layer 205 is exposed.

Exposing the multiple doped layers 200 can be possible because the multiple doped layers 201, 203, 205 and detaching layer 207 are formed with different film material or formed with same material but with different film density. In other method, by adding physical shock to the detaching layer 207, the detaching layer which has weak crystal lattice structure can be cracked to detaching the single crystalline semiconductor substrate 200 and the multiple doped layers 201, 203, 205.

As a result, n-type doped layer 201, p-type doped layer 203, and n-type doped layer 205 can be formed orderly on the bonding layer 190.

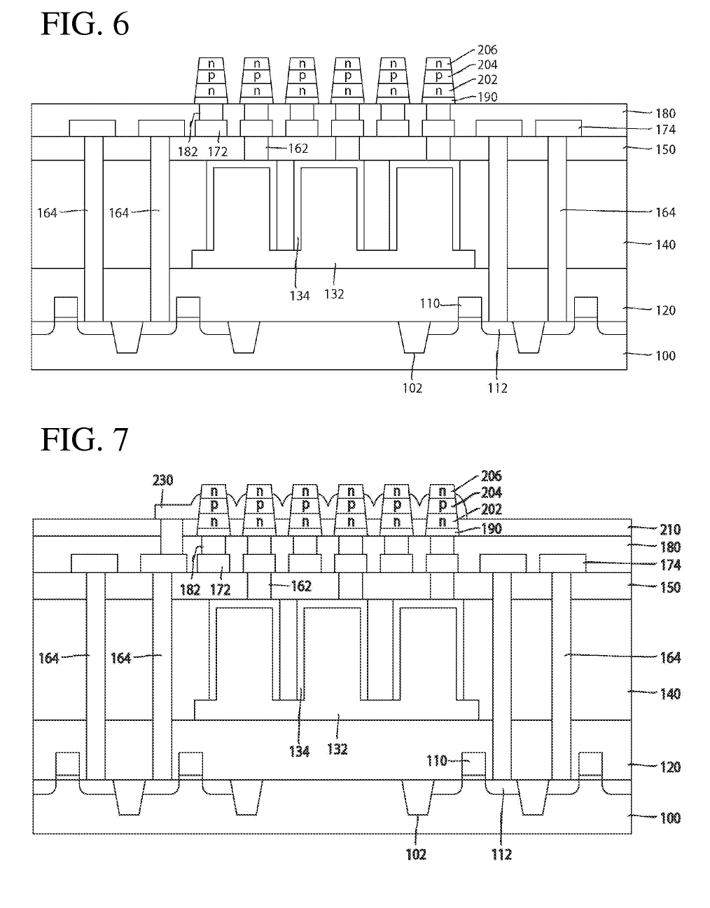

In FIG. 6, pillar shaped semiconductor layer patterns 202, 204, 206 are formed to form transistors with vertical channel structure. The pillar shaped semiconductor patterns 202, 204, 206 are formed by patterning the multiple doped layers 201, 203, 205.

More specifically, the semiconductor patterns 202, 204, 206 can be formed by performing photolithography and etch processes to the multiple doped layers 201, 203, 205. That is, n/p/n types of doped layers patterns can be formed. When forming the semiconductor patterns 202, 204, 206, the bonding layer can be also etched. In this case, bonding layer patterns 190 can be formed under the pillar shaped semiconductor patterns 202, and part of the surface of the third interlayer dielectric film can be exposed.

In FIG. 7, gate electrodes 220 are formed as spacer shape at each side of the semiconductor patterns 204 among the semiconductor patterns 202, 204, 206.

More specifically, a fourth interlayer dielectric film 230 is formed on the third interlayer dielectric film 180 to cover sidewalls of the semiconductor patterns 202 to which the bonding layer 190 is interfaced. As following steps, in the third and fourth interlayer dielectric films 180, 210, contact plugs 206 are formed to connect logic devices in the lower region and gate conductor 220. And then, gate dielectric and gate conductor are deposited conformal to the surface of the semiconductor patterns 204, 206 on the fourth interlayer dielectric film 201. The gate dielectric and gate conductor are anisotropic etched to form spacer shaped gate electrode 220 which surrounds the channel region (p-type semiconductor layer) of the pillar. This forms the vertical channel transistors.

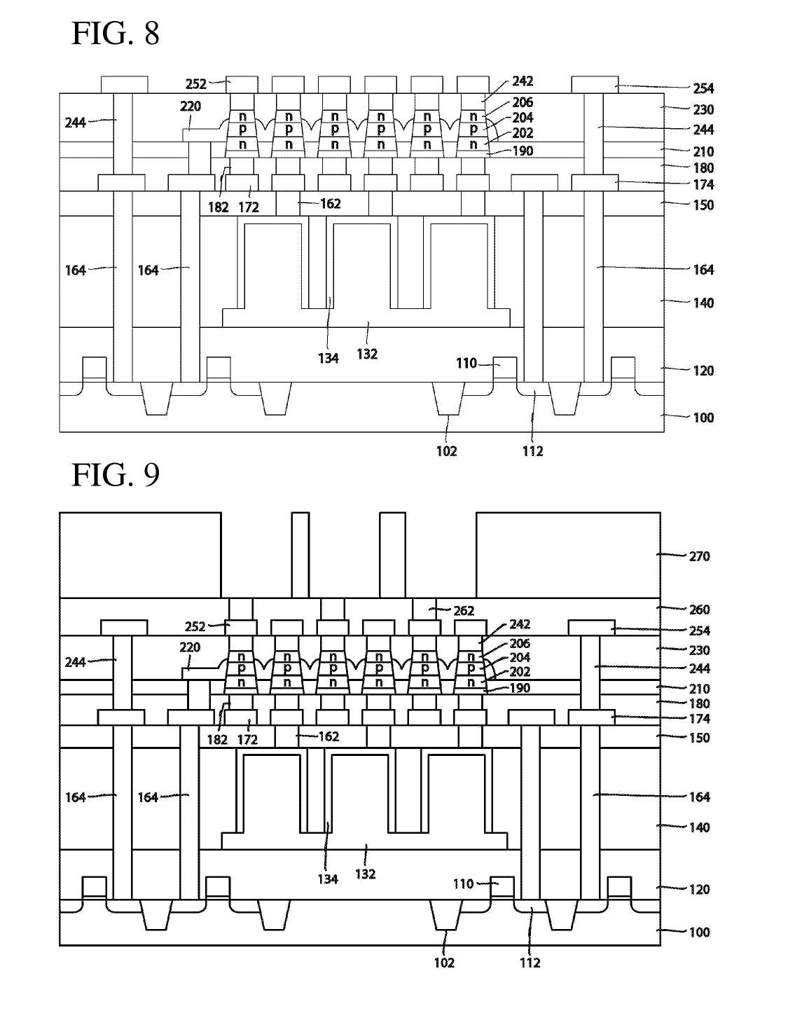

In FIG. 8, a fifth interlayer dielectric film 230 is formed to cover the pillar shaped semiconductor patterns 202, 204, 206 and gate electrodes 220. After this step, contact plugs 242 are formed which are individually connected to the source/drain regions 206 in the fifth interlayer dielectric film 230, and at the same time contact plugs 244 are formed which are connected to the logic devices. And then wirings 252, 254 are formed on the each of the contact plugs 242, 244. Among the wirings, the wirings on the semiconductor patterns 202, 204, 206 which are connected to the capacitors 132, 134 are bit lines.

In FIG. 9, a sixth interlayer dielectric film 260 is formed after formation of wirings 252, 254, and then contact plugs for upper region storage nodes are selectively formed to be connected to the wirings 252.

Storage nodes which are contact plugs for the upper region storage nodes to be connected to the second electrode (that, is storage node electrodes) and source/drain regions 206 are formed on the semiconductor patterns 202, 204, 206 which are not connected to the lower regions capacitors 132, 134.

As following steps, upper region storage devices, which are upper region capacitors, are formed on the sixth interlayer dielectric film 260. The upper region storage devices (capacitors) are formed symmetrical to the lower region storage devices (capacitors 132, 134), and can be electrically connected to the switching devices which are not connected to the lower region storage devices. Also, the switching devices which are connected to the lower region storage devices can be formed to be alternatively located to the switching devices which are connected to the upper regions storage devices. In this embodiment of the invention, the upper regions storage devices can be formed as cylinder type capacitors.

More specifically, a seventh interlayer dielectric film 270 is formed in enough thickness on the sixth interlayer dielectric film 260. The seventh interlayer dielectric film 270 is then patterned and exposed to form openings on the top surface of the contact plugs 262 for the upper region storage nodes.

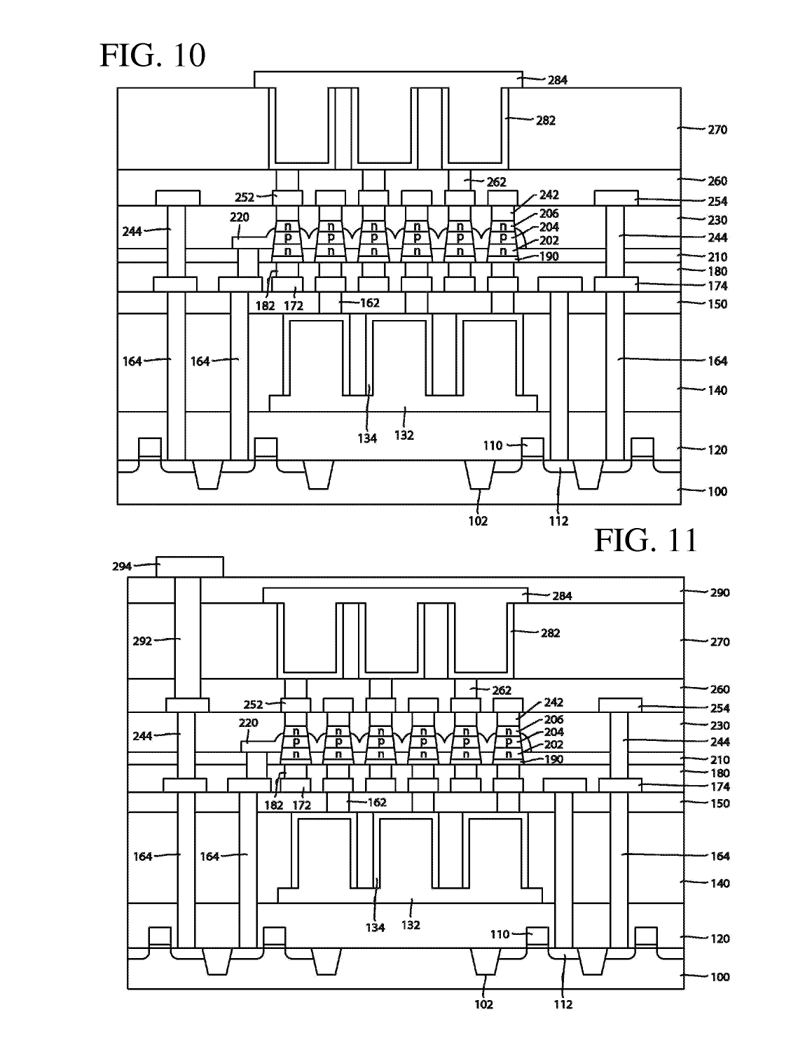

In FIG. 10, conducting film for second electrode are deposited conformal to the surface of the seventh interlayer dielectric film openings. And then, dielectric film (not illustrated) with good gap filling characteristics is deposited, and then the second electrode conductor film is planarized until the seventh interlayer dielectric film 270 is exposed. Then dielectric film (not illustrated) is formed conformal to the surface of the second electrodes 282, and a first electrode conductor film is deposited to fill in the inside of the second electrode 282. And then the first electrode film is patterned to form the first electrode 284.

In FIG. 11, an eighth interlayer dielectric film 280 can be formed on the seventh interlayer dielectric film to cover the upper region storage devices 282, 284. Finally, contact plugs 292 and metal wirings 294 can be formed to be connected to the logic devices.

In accordance with the first embodiment of this invention, switching devices with vertical channels can be formed by bonding semiconductor substrates on the logic devices, and the storage devices can be formed at upper and lower regions of the switching devices.

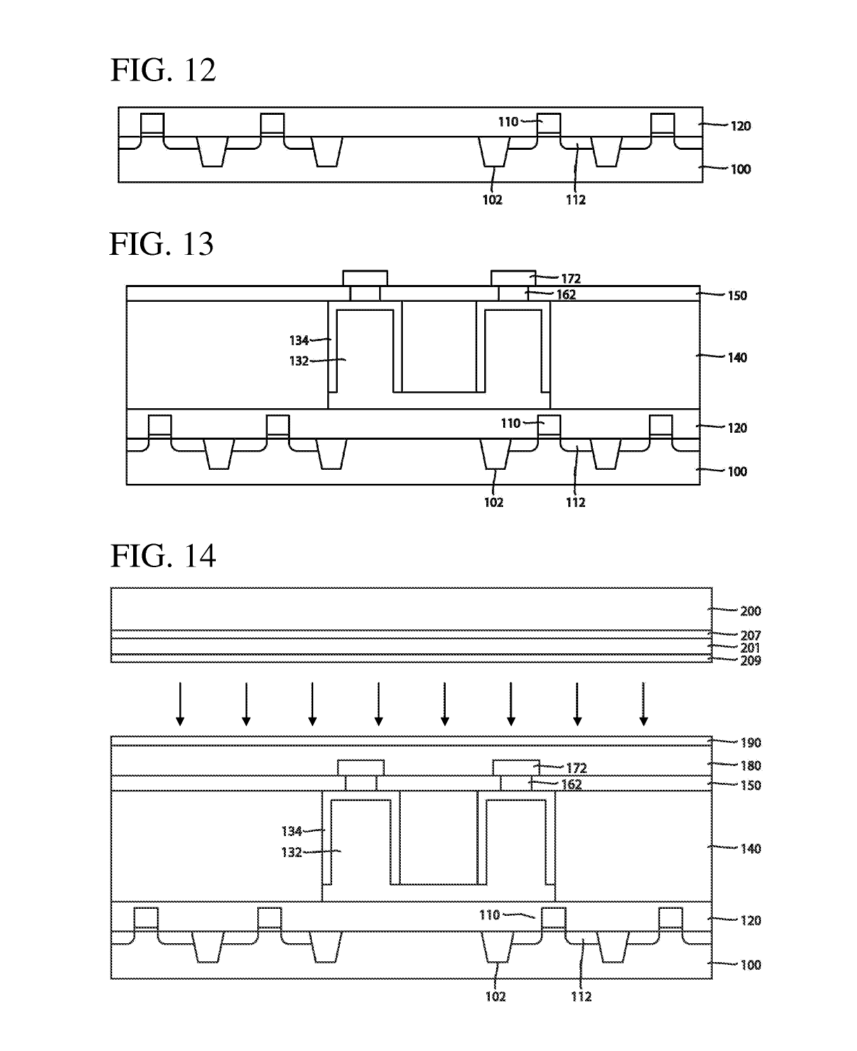

The FIGS. 12 to 19 illustrates the steps in fabricating the semiconductor memory device of a second embodiment of this invention.

In FIG. 12, logic devices are formed on the first semiconductor substrate 100. The logic devices can be formed by forming NMOS and PMOS transistors 110, 112, resistors (not illustrated), diodes (not illustrated) and wirings (not illustrated).

More specifically, active regions can be defined by forming isolations 102 in the first semiconductor substrate 100. Then, gate dielectric and gate conductor film is stacked and patterned to form gate electrode in the active regions on the first semiconductor substrate 100. After gate electrodes 110 are formed, dopants are ion-implanted at each side of the gate electrodes 110 to form source/drain regions 112. This forms transistors on the first semiconductor substrate 100.

Then, a first interlayer dielectric film 120 is formed by depositing dielectric film with good step coverage on the transistors 110, 112. Resistors (not illustrated), diodes (not illustrated) and wirings (not illustrated) can be formed inside the first interlayer dielectric film 120.

In FIG. 13, lower regions storage devices are formed on the first interlayer dielectric film 120. Specifically, enough thickness of conducting film for the first electrode formation is deposited, and then the conductive film is exposed and etched to form pillar shaped first electrodes 132. The first electrodes 132 which are biased with ground can be electrically connected each other.

After forming the first electrodes 132, a dielectric film (not illustrated) and a conducting film for second electrode is deposited conformal to the surface of the first electrode 132. The second conductive film for second electrode is then etched to be separated as second electrodes 134. By this process, the second electrodes 134 can be separated from each other while covering the first electrodes conformally. In this case, the second electrodes 134 are storage node electrodes, and can have cylinder shapes with open bottoms.

After forming the capacitors 132, 134, a second interlayer dielectric film 140, 150 is deposited all over the semiconductor substrate. The surface of the second interlayer dielectric film 140, 150 can be planarized by CMP or etch back processes, and contact plugs 162 and conducting pads 172 which are connected to the second electrode 134.

The lower region storage devices on the first interlayer dielectric film 120 can be formed with refractory metals to reduce affect from the following high temperature process steps afterward. The refractory metals are known to have low resistivity, low stress, good step coverage and good thermal expansion coefficient. The first and second electrodes 132, 134 of the capacitors, contact plugs 162 and conducting pads 172 can be formed with refractory metals. The refractory metals can be, for example, Tungsten (W), Titanium (Ti), Molybdenum (Mo), Tantalum (Ta), Titanium Nitride (TiN), Tantalum Nitride (TaN), Zirconium Nitride (ZrN), or an alloy formed by combination of the Tungsten Nitride (TiN) and those other materials. Also, the first and second electrodes 132, 134 of the capacitors can be formed with poly silicon film. By using these materials, electrical characteristics and reliabilities of the lower region storage devices can be maintained even after high temperature processes afterwards, especially formation of the switching devices.

In FIG. 14, a third interlayer dielectric film 180 is deposited to cover the conducting pads 172 on the lower regions capacitors 132, 134, and the film 180 is planarized. Then a bonding layer 190 is formed on the third interlayer dielectric film 180, and this bonding layer 190 is for bonding a second semiconductor substrate on the third interlayer dielectric film 180.

The bonding layer 190 can be formed with, for example, photo-setting adhesive such as reaction-setting adhesive, thermal-setting adhesive, photo-setting adhesive such as UV-setting adhesive, or anaerobe adhesive. Further, the bonding layer can be, such as, metallic bonds (Ti, TiN, Al), epoxy, acrylate, or silicon adhesives.

When the bonding layer 190 is formed with metallic materials, the metallic material can be formed with material that has lower melting point than those of conducting materials used for contact plugs 162 and conducting lines 172. And, the bonding layer 190 can be formed with materials that can be re-flowed at a lower temperature planarization process so that it can prevent formation of voids between the second semiconductor substrate 200 and the bonding layer 190. The bonding layer 190 can increase the bonding strength when bonding the second semiconductor 200 onto the bonding layer 190, and also decrease micro defects during the bonding process.

As a following step, the second semiconductor substrate 200 is bonded onto the bonding layer 190. Specifically, the second semiconductor substrate 200 can be a single crystalline semiconductor substrate which includes doped layer 201 which is included in pre-defined depth from the surface of the second semiconductor substrate 200. The doped layer 201 can be formed by ion-implanting dopants into the single crystalline semiconductor substrate, or adding dopants during an epitaxial process to form a single crystalline semiconductor substrate.

Also, the second semiconductor substrate 200 includes a detaching layer 207 at the interface of the doped layer 201 and the second single crystalline semiconductor substrate. The detaching layer can be porous layer, oxide film, nitride film, organic bonding film, or strained layer such as Si—Ge interface. Also, bonding layer 209 can be formed on the doped layer 201.

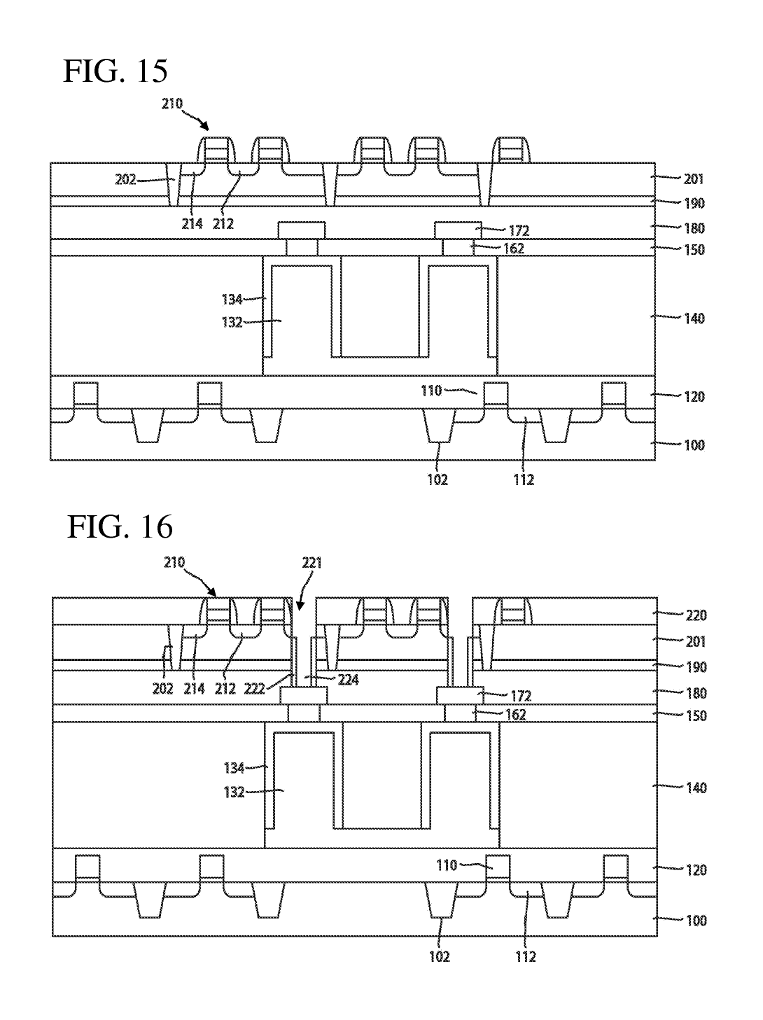

In FIG. 15, after completely bonding the second semiconductor substrate 200 on the bonding layer 190, all of the second semiconductor substrate 200 is removed only except the single crystalline semiconductor doped layer 201. As a result, single crystalline semiconductor doped layer 201 which has n-type or p-type dopants can be formed on the bonding layer 190 which is formed with metallic material.

More specifically, after bonding, the surface of the single crystalline semiconductor substrate 200 is grinded, polished, or etched until the detaching layer 207 is exposed. After the detaching layer 207 is exposed, anisotropic or isotropic etch process is performed to expose the surface of the doped layer 201.

Exposing the doped layer 201 can be possible because the doped layer 201 and detaching layer 207 are formed with different film material or formed with same material but with different film density. In other method, by adding physical shock to the detaching layer 207, the detaching layer which has weak crystal lattice structure can be cracked to detaching the single crystalline semiconductor substrate 200 and the doped layer 201.

As following steps, transistors with horizontal channels can be formed on the bonded single crystalline semiconductor layer 201.

More specifically, active regions are defined by forming isolations 202 in the boded single crystalline semiconductor doped layer 201. Then, gate dielectric film and gate conductor film are deposited and patterned on the single crystalline semiconductor doped layer 201 to form gate electrodes 210. Source/drain regions 212, 214 are formed by doping the single crystalline semiconductor doped layer 201 at each side of the gate electrodes 210. The neighboring gate electrodes 210 can share common source regions 212. Drain regions 214 can be formed in the single crystalline semiconductor doped layer 201 near sidewall of the gate electrode 210 which apart (the other side) from the source regions 212. Also, the certain drain regions 214 can be formed on the lower region capacitors 132, 134 when forming the transistors.

The source/drain regions 212, 214 of each side of the gate electrode 210 can be formed by ion-implantation and annealing process. The ion-implantation and annealing process can be performed at temperatures of between about 800° C. (degrees Celsius) to about 850° C. When the process is held a high temperature, the lower regions storage devices which are formed with refractory metals can be prevented from decreasing reliability by the high temperature.

In FIG. 16, a fourth interlayer dielectric film 220 is formed to cover the transistors 210, 212, 214 formed on the second semiconductor substrate 200. Then, contact holes 221 are formed by penetrating the fourth interlayer dielectric film 220 and the second semiconductor substrate 200. The contact holes 221 expose the conducting lines 172 on the lower region capacitors 132, 134.

After forming the contact holes 221, dielectric film is deposited along with the surface of the contact holes 221, and then anisotropic etched to leave insulating spacer 222 on the inner wall of the contact holes 221. The insulating spacer 222 can prevent the bonding layer 190, which is formed with conducting material, from exposed to other films or layers.

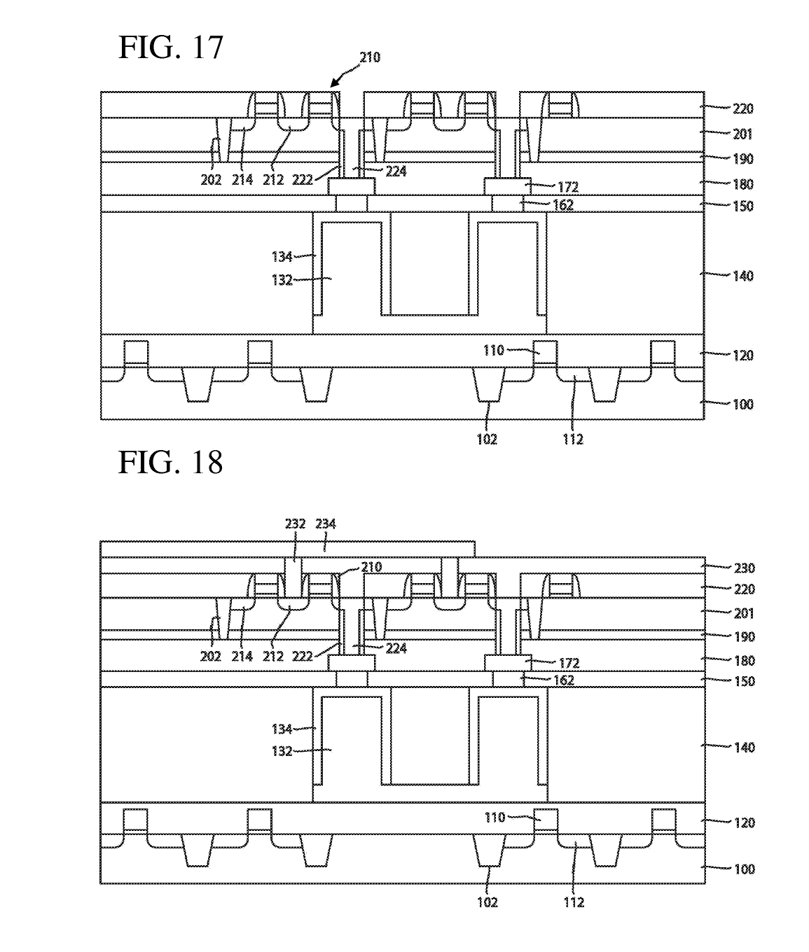

In FIG. 17, contact plugs 224 for lower regions storage nodes can be formed by filling in the contact holes 221 with conducting material. The lower region storage nodes can be filled into the surface of the second semiconductor substrate 200, and then electrically connected to the drain regions 214 in the second semiconductor substrate 200.

In FIG. 18, a fifth interlayer dielectric film is formed on the fourth interlayer dielectric film, and the fifth interlayer dielectric film can fill in the contact holes. As a following step, contact plugs 232 for bit line are formed in the fourth and fifth interlayer dielectric films 220, 230. The contact plugs 232 are connected to the common source regions 212. When forming the contact plugs 121 for bit lines, contact plugs which are electrically connected to the logic devices can be also formed. In following steps, bit lines 234 are formed on the contact plugs 232 for bit lines are formed perpendicular to the gate conductors. Also, conducting lines (not illustrated) which are connected to the logic devices can be formed when forming the bit lines 234.

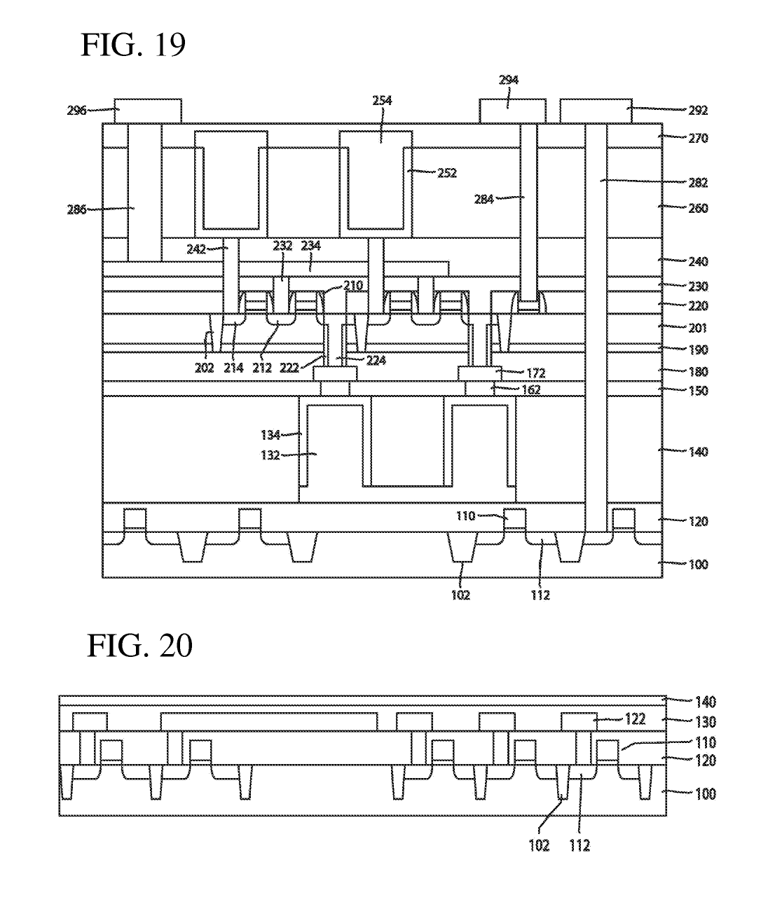

In FIG. 19, a sixth interlayer dielectric film 240 which covers the bit lines 234 are formed, and then contact plugs 242 for upper region storage nodes which are connected to the drain regions 214 are formed in the sixth interlayer dielectric films 240.

In the FIG. 19, it is illustrated as the contact plugs 242 and bit lines 234 are piled up on each other, but in three dimensional view, the bit lines 234 and contact plugs for the storage nodes are electrically isolated.

Open top cylinder shaped second electrodes 252 can be formed on the contact plugs 242 for the upper storage nodes, as explained in the first embodiment of this invention. Then, a dielectric film (not illustrated) and the first electrode 254 can be formed on the second electrode 252. The first electrode 254 can fill in the inside of the cylinder shaped second electrode 252.

As following steps, an eighth interlayer dielectric film 270 is formed to cover the upper region capacitors 252, 254, and contact plugs 282 which are connected to the logic devices 110, 112 and final metal interconnections 292 are formed.

FIGS. 20 to 27 illustrate steps in a method of fabricating semiconductor memory device in accordance with a third embodiment of this invention.

In FIG. 20, a first semiconductor substrate with logic device on it is provided.

Transistors 110, 112 are formed on the first semiconductor substrate 100, and then first interlayer dielectric film 120 is formed to cover the transistors 110, 112. Contact plugs 120 are formed in the first interlayer dielectric film 120, and wirings 122 are formed on the contact plugs. Then, a second interlayer dielectric film is formed to cover the wirings 122, and then top of the second dielectric film is planarized. The logic devices are formed on the first semiconductor substrate 100, and then a bonding layer 140 is formed on the second interlayer dielectric film 130.

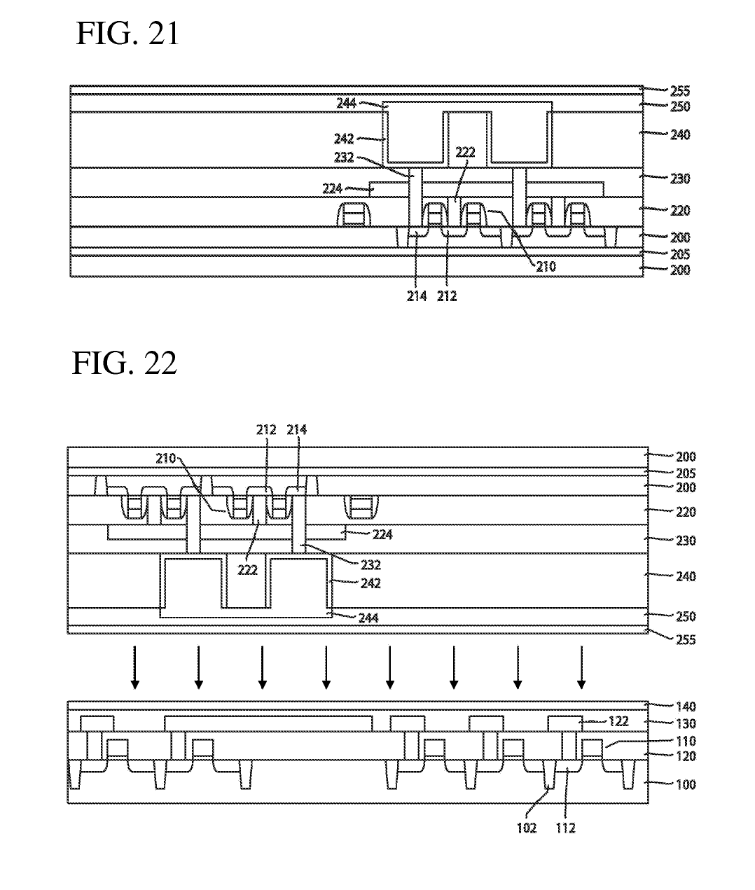

In FIG. 21, a second semiconductor substrate 200 is provided. The second semiconductor substrate 200 includes switching devices 210, 212, 214 and first storage devices 242, 244. The second semiconductor substrate 200 can be a single crystalline semiconductor substrate which includes a doped layer in pre-defined depth. The single crystalline semiconductor substrate includes doped layers of pre-defined depth from the surface. The single crystalline semiconductor substrate also includes a detaching layer 205 in a pre-defined depth to be interfaced with the doped layer.

As following steps, transistors 210, 212, 214 with horizontal channels are formed on the second semiconductor substrate 200 as switching devices. After forming the transistors, a first interlayer dielectric film is deposited to fill in the transistors 210, 212, 214, and then bit line contact plugs 222 which are connected to the common source region 212 of the transistors are formed, and bit line 224 are formed as well step by step. A second interlayer dielectric film 230 is formed to cover the bit lines, and contact plugs for storage nodes 232 are formed in the first and second interlayer dielectric films. Then, capacitors 242, 244 are formed on each of the contact plugs 232 for storage nodes. As following steps, a third interlayer dielectric film 240 with enough thickness are formed on the second interlayer dielectric film 230, and cylinder shaped storage nodes electrodes 242 are formed in the third interlayer dielectric film 240. A dielectric film (not illustrated) and plate electrode 244 are formed step by step on the storage node electrodes 242. Then, a fourth interlayer dielectric film 250 are deposited to cover the capacitors 242, 244, and then a bonding layer 255 is formed on the fourth interlayer dielectric film.

In FIG. 22, the first semiconductor substrate 100 and the second semiconductor substrate 200 are bonded each other.

Specifically, the bonding layer 140 on the first semiconductor substrate 100 and the bonding layer 255 on the second semiconductor substrate 200 are to be faced each other and bonded. As a result, on the logic devices 110, 112, 122, the first storage devices 242, 244 and switching devices 210, 212, 214 are formed in this order.

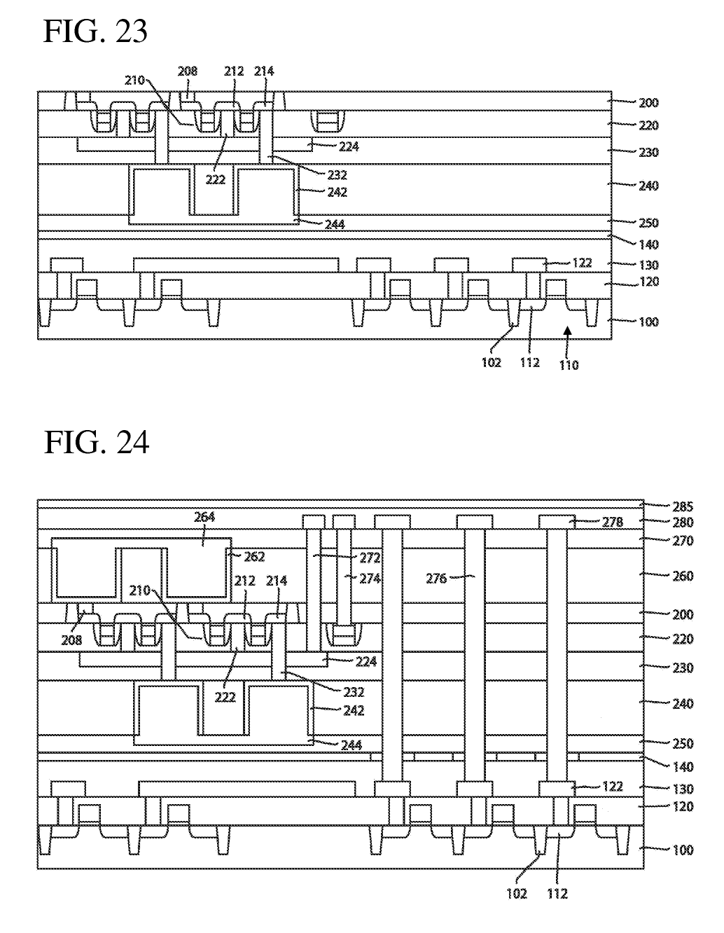

In FIG. 23, part of the backside of the second semiconductor substrate 200 is removed. The removal can be controlled by detaching layer which is formed inside the second semiconductor substrate 200.

Then, contact plugs 208 are formed in the second semiconductor substrate which are connected to the pre-defined drain regions of the transistors.

In FIG. 24, second storage devices 262, 264 are formed on the backside of the second semiconductor substrate 200. Specifically, capacitors 262, 264 can be formed on the backside of the semiconductor substrate 200, and the capacitors 262, 262 are connected to the contact plugs 208. More specifically, open top cylinder shaped storage node electrodes 262 are formed on the backside of the second semiconductor substrate 200, then a dielectric film (not illustrated) and a plate electrode 264 are formed on the surface of the storage node electrodes 262.

After forming the capacitors 262, 264, contact plugs 272, 274, 276 and conducting lines 278 are formed to be matched with bit lines 224, gate electrodes 210, and logic devices 110, 112.

Then, interlayer dielectric film 280 is formed to cover the conducting lines 278 and a bonding layer 285 is formed on the interlayer dielectric film 280.

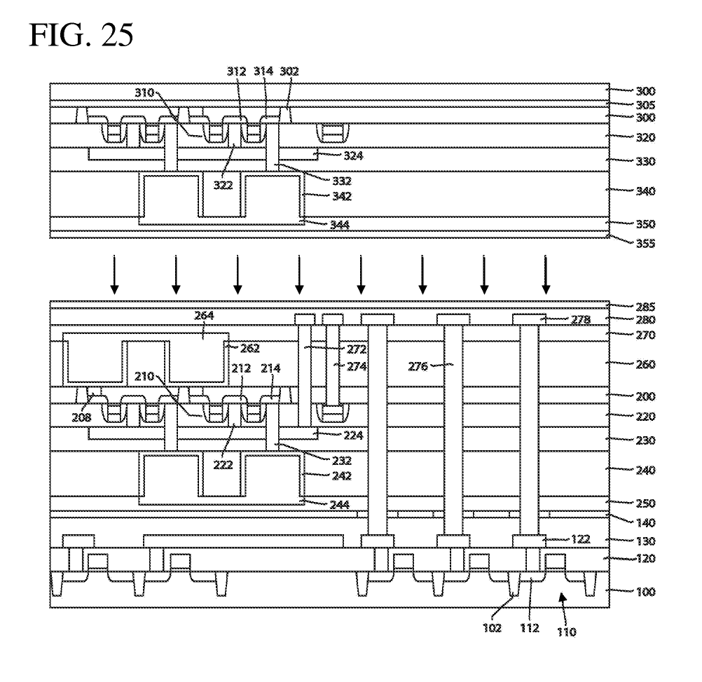

In FIG. 25, a third semiconductor substrate is provided. The third semiconductor substrate includes switching devices 310, 312, 314 and third storage devices 342, 344. A bonding layer 355 is formed on the third semiconductor substrate 300, and then bonded to the bonding layer 285 of the second semiconductor substrate 200. Forming the switching devices 310, 312 and the third storage devices 342, 344 on the third semiconductor substrate 300 will be practically same as forming switching devices 110, 112 and the second storage devices 210, 212, 214 on the second semiconductor substrate 200.

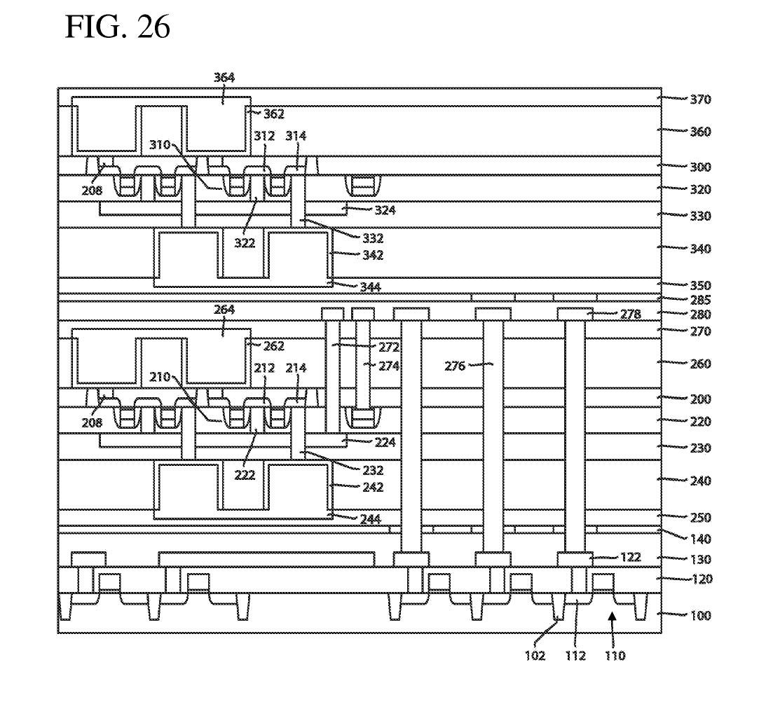

FIG. 26 illustrates removing part of the backside of the third semiconductor substrate 300, and forming the fourth storage devices 362, 364 which are electrically connected to the switching devices 310, 312.

Then, contact plugs for storage nodes are formed to be connected to the drain regions 314 of the transistors in the third semiconductor substrate 300. After this, capacitors 362, 364 are formed on the contact plugs for the storage nodes. As a result, the third storage devices 342, 344 are formed below the switching devices 310, 312, and the fourth storage devices 362, 364 are formed above the switching devices 310, 312.

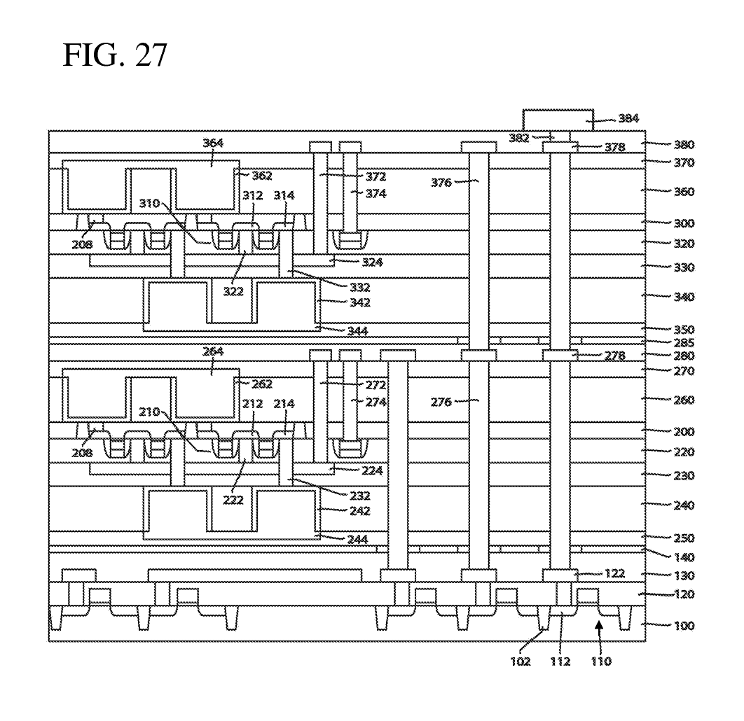

In FIG. 27, contact plugs 372, 374 and conducting lines 378 are formed to be connected each to the bit lines 324 and gate electrodes 310. Also, contact plugs 378 and conducting lines 378 formed to be connected to the logic devices 110, 112, 122 in the lower region. And then, final metal wirings 384 are formed on top of the contact plugs 378.

As described in this embodiment, switching devices and storage devices can be formed on the logic devices by bonding a semiconductor substrate with logic devices and another semiconductor substrate with switching and storage devices. Also, by repeating the bonding the semiconductor substrate with switching and storage devices, the chip density of the semiconductor memory device can be much improved.

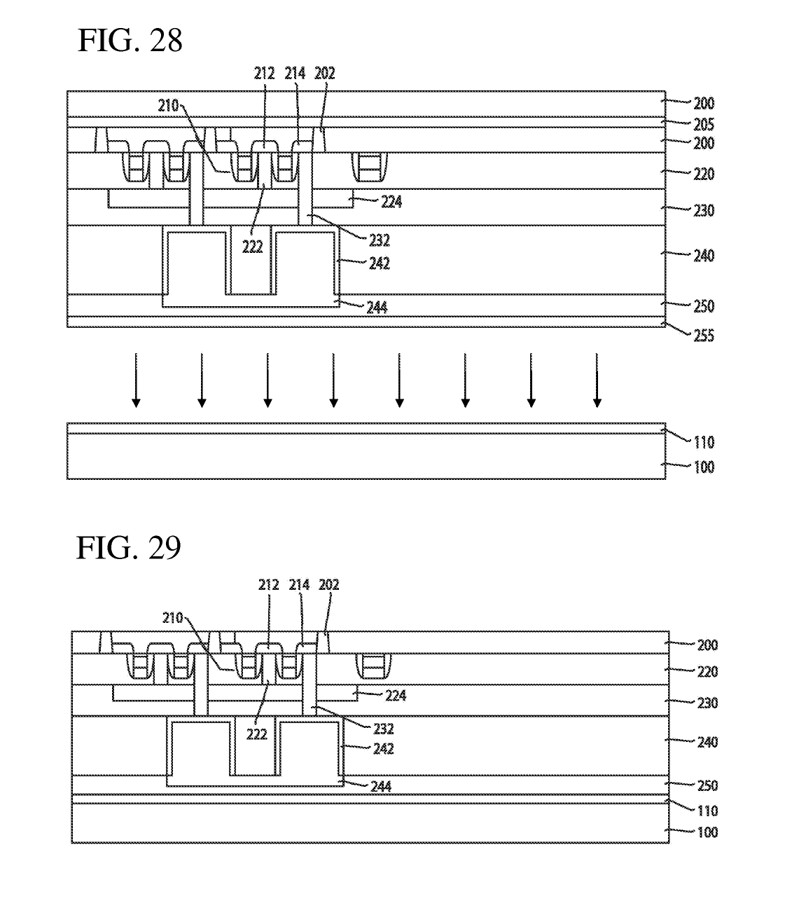

FIGS. 28 to 37 are sectional views of the semiconductor memory device fabricated in accordance with this invention. It will be described with a fourth embodiment of this invention.

In FIG. 28, a first semiconductor substrate 100 is provided with a bonding layer 110 if formed on the surface. The first semiconductor substrate 100 can be a dummy substrate with no doped layers or other devices are formed.

A second semiconductor substrate is also provided. The second semiconductor substrate includes switching devices 210, 212, 214 and first storage devices 242, 244. The second semiconductor substrate also includes a detaching layer 205 which will be used as etch stopper when removing part of the second semiconductor substrate in the following process steps. The same method can be used as explanation for the FIG. 21 when forming the switching devices 210, 212, 214 and the first storage devices 242, 244 on the second semiconductor substrate 200. After forming the interlayer dielectric film 250 which covers the first storage devices 242, 244, a bonding layer 255 is formed on the interlayer dielectric film 250.

Then, the bonding layer 110 on the first semiconductor substrate 100 and the bonding layer 255 on the second semiconductor substrate 200 are bonded each other face to face. As a result, the second semiconductor substrate 200 are located on top of the first semiconductor substrate 100, and the backside of the second semiconductor substrate 200 are now exposed to top.

In FIG. 29, as a result of bonding, the storage devices 242, 244 and the switching devices 210, 212 are arranged in this order. Then part of the top surface (which was backside of the second semiconductor substrate before bonding) of the second semiconductor substrate is removed to the detaching layer 205 in the second semiconductor substrate.

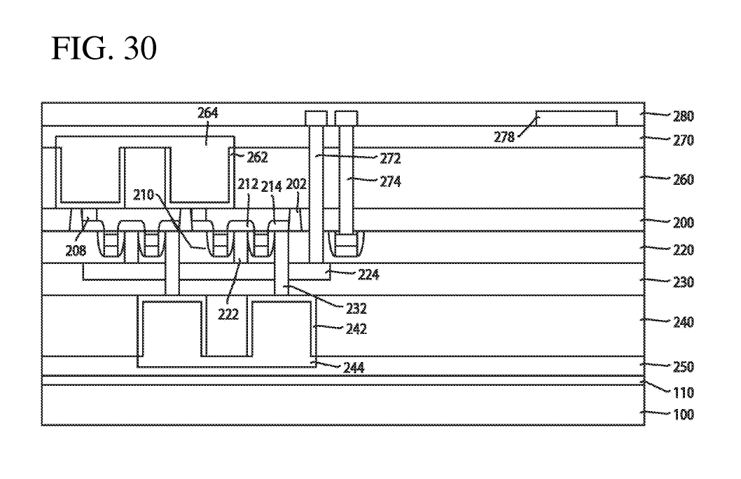

In FIG. 30, second storage devices 262, 264 are formed on the second semiconductor substrate 200. Specifically, storage node contact plugs 208 are formed to be contacted to the drain regions 214 in the second semiconductor substrate 200. Then, capacitors 242, 244 are formed on the storage node contact plugs 208. And then, bit lines 224 and contact plugs which are connected to the gate electrodes 210 and wirings 278 can be formed.

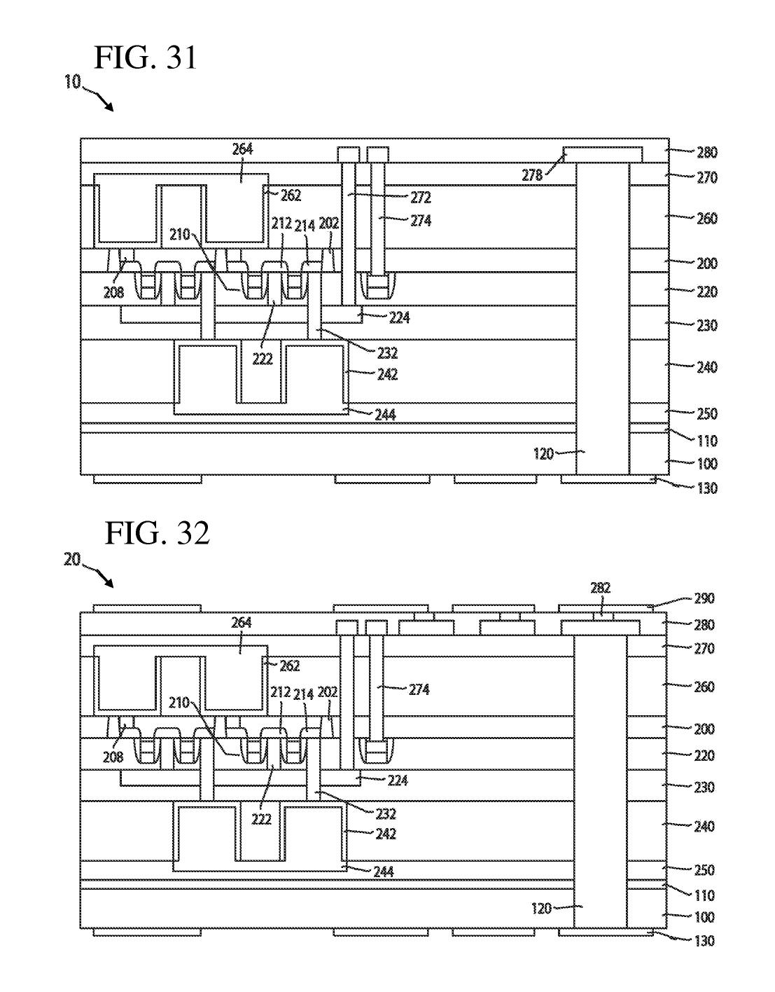

In FIG. 31, contact plugs 120 are formed to be connected from the first semiconductor substrate 100 to the wirings 278 by following process steps. This completes formation of a first semiconductor device.

In FIG. 32, a second semiconductor device is provided which has bonding layers on the backside and top most layer of the first semiconductor substrate 100. The process steps and method for providing the second semiconductor device is practically same as providing the first semiconductor device. The only differences are, the second semiconductor device can have bonding layers 130, 290 on the top surface of the first storage devices 242, 244 and backside of the dummy semiconductor substrate 100.

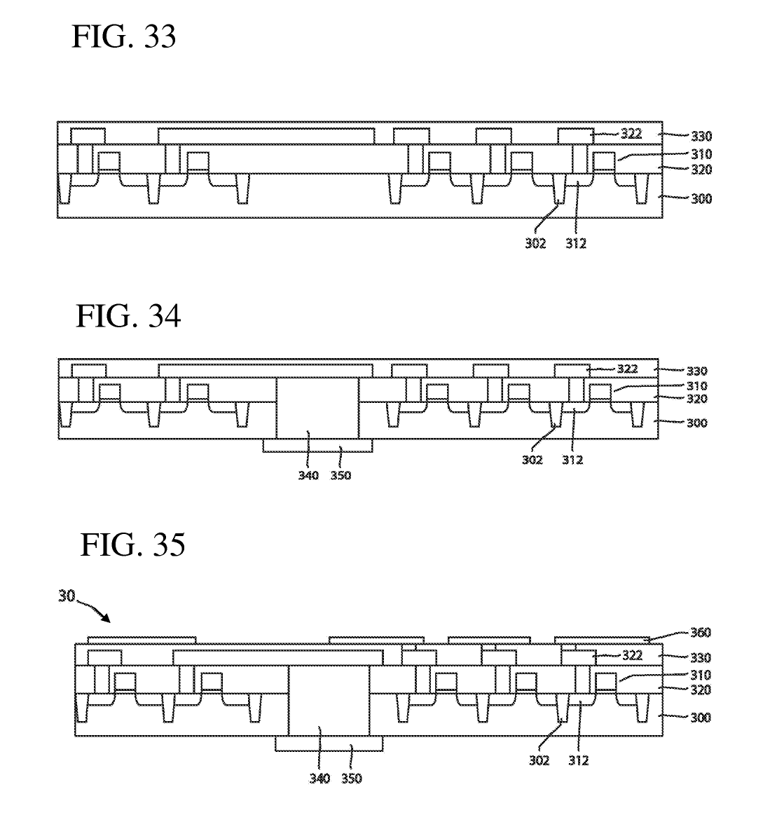

In FIG. 33, a third semiconductor substrate 300 is provided. Transistors 310, 312 and wirings 322 can be formed on the third semiconductor substrate 300.

As illustrated in FIG. 34, contact plugs 340 are formed. The contact plugs 340 are connected from the backside of the third semiconductor substrate 300 to the wirings 322 on the third semiconductor substrate 300. The contact plugs 340 can be formed by penetrating the third semiconductor substrate 300. Wirings 350 can be formed on the backside of the third semiconductor substrate 300 which are electrically connected to the logic devices 310, 312.

In FIG. 35, a bonding layer 360 is formed on top of the third semiconductor substrate 300. This bonding layer 360 is to bond other semiconductor devices (10, 20 of the FIG. 31) on top of the third semiconductor substrate 300. The bonding layer 360 can be formed with conducting materials, and this allows electrical connection between logic devices 310, 312 and other semiconductor devices (10, 20 of the FIG. 31). This completes providing the third semiconductor device 30 which includes logic devices 310, 312.

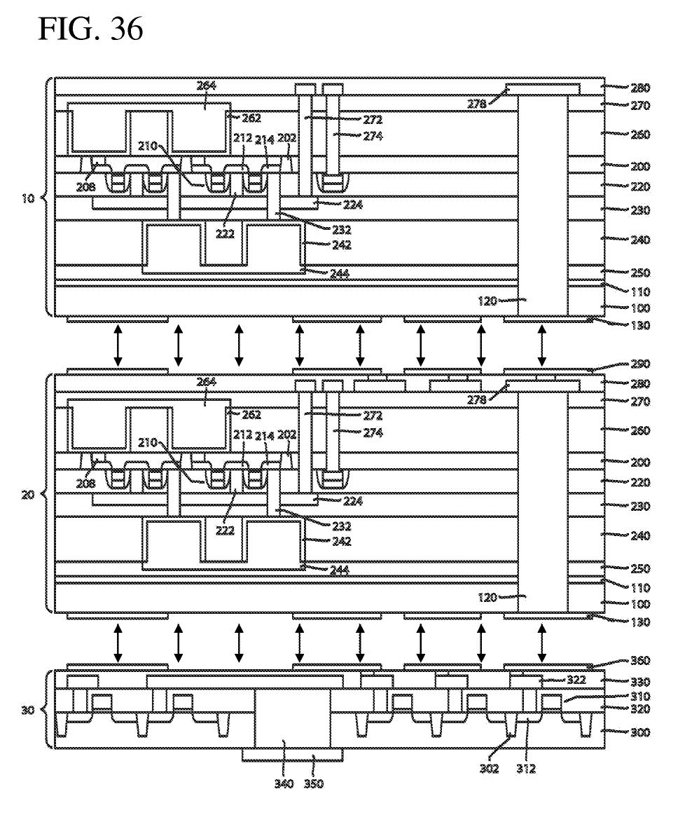

In FIG. 36, the second semiconductor device 20, which includes the third and fourth storage devices 242, 244, 262, 264 and switching devices 210, 212, 214, is bonded to the third semiconductor device 30 which includes logic devices 310, 312. Then, the first semiconductor device 10, which includes the first and second storage devices 242, 244, 262, 264 and the switching devices 210, 212, is bonded to the second semiconductor device 20.

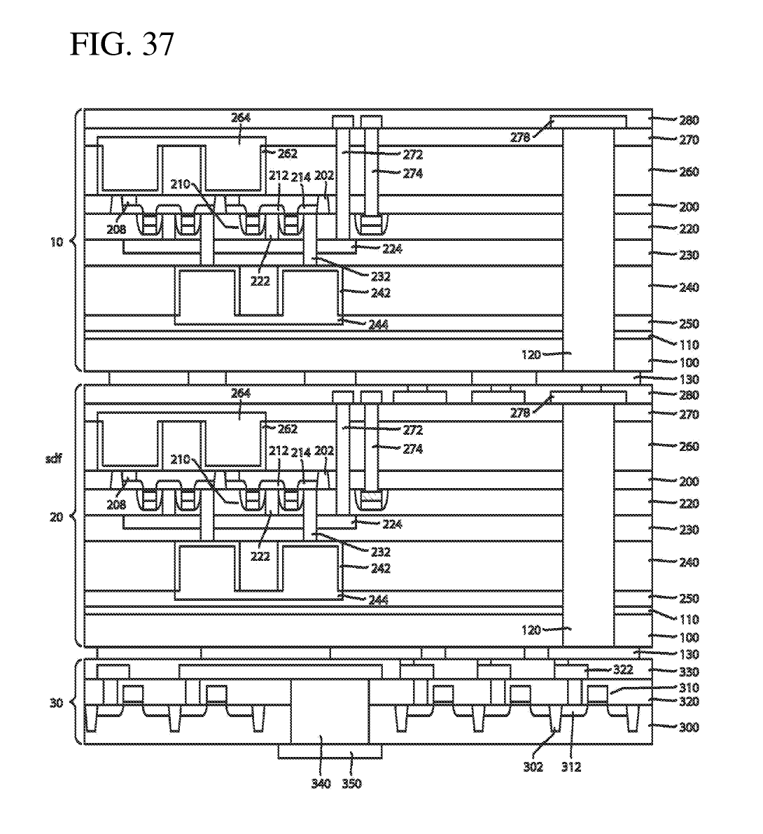

FIG. 37 illustrates completed semiconductor memory device with repeated storage devices and switching devices formed on the logic devices 310, 312. The first to third semiconductor devices can be electrically connected through bonding layers 130, 290 which are formed with conducting material.

The embodiments of the invention described herein are exemplary and numerous modifications, variations and rearrangements can be readily envisioned to achieve substantially equivalent results, all of which are intended to be embraced within the spirit and scope of the invention.

1. A method for fabricating semiconductor memory device, comprising:
providing a first semiconductor substrate;
forming a first storage device on the first semiconductor substrate;
forming a switching device on the first storage device; and
forming a second storage devices on the switching device.

2. The method of claim 1, wherein logic devices are formed below the first storage devices to be electrically connected to the switching devices.

3. The method of claim 1, wherein forming the first or the second storage devices includes, forming first electrodes which is connected to the switching devices; forming a dielectric film on the first electrode; and forming second electrodes on the dielectric film.

4. The method of claim 3, wherein the dielectric film is formed with dielectric film, high-k dielectric film, or phase change film.

5. The method of claim 1, wherein forming the first and second storage devices includes, forming pillar shaped first electrodes which are connected to the switching devices; forming a dielectric film on surface of the first electrodes conformal; and forming second electrodes on surface of the dielectric film conformal.

6. The method of claim 1, wherein forming the first and second storage devices includes, forming cylinder shaped first electrodes which are connected to the switching devices; forming a dielectric film on surface of the first electrodes conformal; and forming second electrodes on surface of the dielectric film conformal to fill up the inside of the cylinder shaped first electrodes.

7. The method of claim 1, wherein forming the switching devices includes, bonding a second semiconductor substrate on the first storage devices; and forming second switching devices on the second semiconductor substrate.

8. The method of claim 7, wherein forming the switching devices further includes before forming the switching devices, forming insulating layer which covers the first storage devices; and bonding the second semiconductor substrate on the insulating layer.

9. The method of claim 8, wherein bonding the second semiconductor substrate is comprising of, providing a single crystalline semiconductor substrate; forming multiple doped layers which is uniformly formed in a pre-defined depth from the surface of the single crystalline semiconductor substrate; bonding the single crystalline semiconductor substrate to the top surface of the first insulating layer to face to face; and removing part of the single crystalline semiconductor substrate until the surface of the doped layers are exposed.

10. The method of claim 9, wherein further forming a detaching layer in a pre-defined depth to be contacted to the multiple doped layers in the single crystalline semiconductor substrate, after forming the multiple doped layers.

11. The method of claim 10, wherein forming the detaching layer is forming porous layer.

12. The method of claim 9, wherein forming the multiple doped layers is forming p-type, n-type, p-type doped layers or forming n-type, p-type, n-type doped layers from the surface of the single crystalline semiconductor substrate.

13. The method of claim 9, wherein the method further includes after bonding the second semiconductor substrate, forming doped layers patterns by patterning the multiple doped layers; and forming second storage devices on the surface of the doped layers patterns.

14. The method of claim 13, wherein the multiple doped layers patterns include channel regions, and source regions and drain regions at the upper and lower side of the channel regions.

15. The method of claim 14, wherein gate conductors are formed to complete the switching devices after forming the doped layers patterns to surround the channel regions.

16. The method of claim 8, wherein bonding the second semiconductor substrate is comprising,
providing single crystalline semiconductor substrate which includes doped layers in which dopants are doped in pre-defined depth from the surface;
bonding the single crystalline semiconductor substrate to the top surface of the first insulating layer to face the surface of the doped layers; and
removing part of the single crystalline semiconductor substrate until the surface of the doped layers is exposed.

17. The method of claim 16, wherein the single crystalline semiconductor substrate further includes a detaching layer which is formed at the pre-defined depth in where the doped layers is faced in the single crystalline semiconductor substrate.

18. The method of claim 16, wherein forming the switching devices further includes forming gate electrodes on the second semiconductor substrate, and forming doped layers at each side of the gate electrodes.

19. The method of claim 18, wherein forming the first storage devices includes forming wiring layers formed with metal or refractory metals.

20. The method of claim 19, wherein the wiring layers are formed with Cobalt (Co), Titanium (Ti), Tungsten (W), Nickel (Ni), Platinum (Pt), Hafnium (Hf), Molybdenum (Mo), Palladium (Pd), Titanium Nitride (TiN), Tantalum Nitride (TaN), Zirconium Nitride (ZrN), Tungsten Nitride, or an alloy formed by combination of those metals.
